(19) United States
(12) Patent Application Publication
(10) Pub. No.: US 2008/0174026 A1
(43) Pub. Date: Jul. 24, 2008

(54) SEMICONDUCTOR DEVICE

(75) Inventor: Terunao HANAOKA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/015,729

(22) Filed: Jan. 17, 2008

(30) Foreign Application Priority Data
Jan. 19, 2007 (JP) 2007-010572

(51) Int. Cl. H01L 23/48

(52) U.S. Cl. 257/773; 257/E23.011

(57) ABSTRACT

A semiconductor device includes a semiconductor substrate provided with an integrated circuit and an electrode electrically coupled to the integrated circuit, a first resin layer formed on a surface of the semiconductor substrate, the surface provided with the electrode, a wiring electrically coupled to the electrode and formed on the first resin layer, a metallic layer formed on the first resin layer, a second resin layer provided with a first through hole overlapped with the wiring and a second through hole for exposing a part of the metallic layer, and an external terminal formed inside the first through hole on the wiring.

The entire disclosure of Japanese Patent Application No. 2007-010572, filed Jan. 19, 2007 is expressly incorporated by reference herein.

### BACKGROUND OF THE INVENTION

1. Technical Field

The present invention relates to a semiconductor device.

2. Related Art

In recent years, packages called a wafer level CSP (Chip Scale Package) have been developed, in which external terminals are formed upon formation of wirings over semiconductor chips. JP-A-2003-282790 is an example of related art. A resin layer is formed under the wirings to distribute and absorb a stress generated in the wirings. However, a surface as an active face provided with an integrated circuit becomes deteriorated in heat release performance when being covered with the resin layer. The wirings are also covered with a solder mask except for lands to be mounted with solder balls, thereby having difficulty of releasing heat. Therefore, when a semiconductor device is mounted on a motherboard, most heat generated in the integrated circuit is concentrated on the external terminals to thereby be transferred to the motherboard. Thus, the motherboard is adversely affected by heat.

### SUMMARY

An advantage of the present invention is to reduce an adverse effect on a motherboard by a resin layer.

According to an aspect of the invention, a semiconductor device includes a semiconductor substrate provided with an integrated circuit and an electrode electrically coupled to the integrated circuit, a first resin layer formed on a surface of the semiconductor substrate, the surface provided with the electrode, a wiring electrically coupled to the electrode and formed on the first resin layer, a metallic layer formed on the first resin layer, a second resin layer provided with a first through hole overlapped with the wiring and a second through hole for exposing a part of the metallic layer, and an external terminal formed inside the first through hole on the wiring.

According to an aspect of the invention, not only the external terminal transfers heat through the wiring, but also the metallic layer receives heat and releases heat through the second through hole. Thus, an adverse effect on a motherboard by heat can be reduced when the semiconductor device is mounted on the motherboard.

It is preferable that the second through hole be formed in a manner to expose an end part of the metallic layer and a part of the first resin layer adjacent to the end part of the metallic layer from the second resin layer.

It is preferable that the second through hole be formed in a manner to expose an entire periphery of the metallic layer from the second resin layer.

It is preferable that the metallic layer have a surface in parallel to the first resin layer, the surface formed in a polygonal shape, and that the second through hole be formed in the second resin layer in a manner to expose a corner of the metallic layer.

It is preferable that the second resin layer cover the entire periphery of the metallic layer.

It is preferable that the second resin layer be further provided with a third through hole overlapped with the metallic layer, and a metallic terminal formed inside the third through hole on the metallic layer.

It is preferable that the second resin layer be provided with a plurality of third through holes, the plurality of metallic terminals be formed by forming at least one metallic terminal inside each of the plurality of third through holes, the plurality of metallic terminals be positioned at a plurality of intersection points of a plurality of first parallel straight lines with a plurality of second parallel straight lines perpendicular to the first straight lines, and that the plurality of metallic terminals be arranged in a manner to set uniform intervals between the adjacent metallic terminals in arrays along either of the first and the second straight lines.

### BRIEF DESCRIPTION OF THE DRAWINGS

The invention will be described with reference to the accompanying drawings, wherein like numbers reference like elements.

FIG. 1 is a view showing a semiconductor device according to a first embodiment of the invention.

FIG. 2 is a cross-sectional view of the semiconductor device shown in FIG. 1 taken along the line II-II.

FIG. 3 is a cross-sectional view of the semiconductor device shown in FIG. 1 taken along the line III-III.

FIG. 4 is a view showing a semiconductor device according to a second embodiment of the invention.

FIG. 5 is a cross-sectional view of the semiconductor device shown in FIG. 4 taken along the line V-V.

FIG. 6 is a view showing a semiconductor device according to a third embodiment of the invention.

FIG. 7 is a cross-sectional view of the semiconductor device shown in FIG. 6 taken along the line VII-VII.

### DESCRIPTION OF EXEMPLARY EMBODIMENTS

### First Embodiment

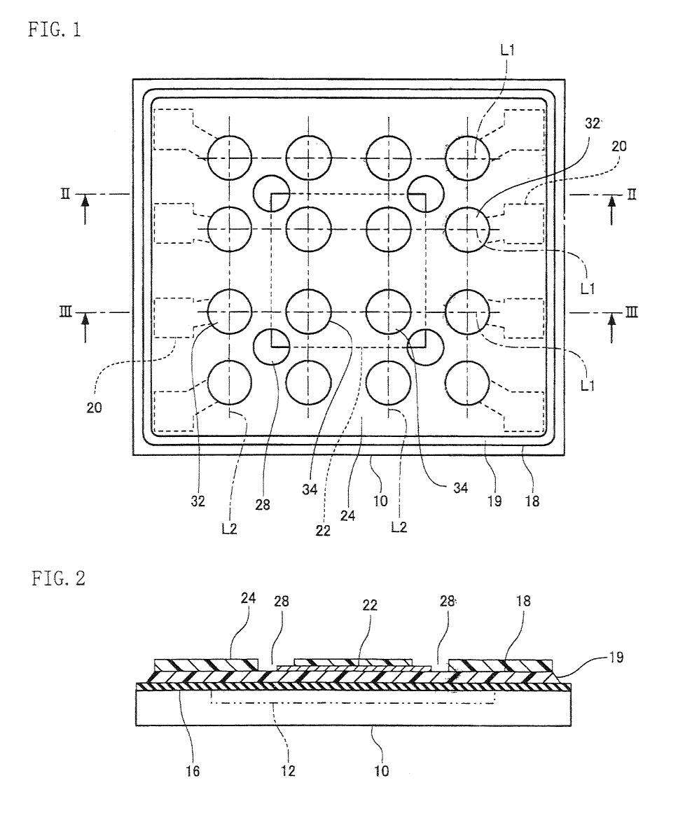

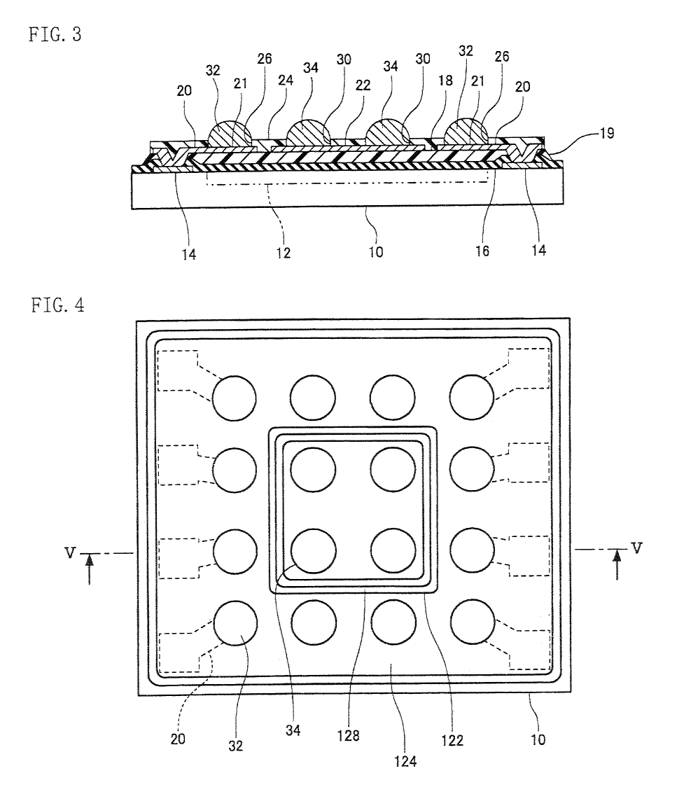

FIG. 1 is a view showing a semiconductor device according to a first embodiment of the invention. FIG. 2 is a cross-sectional view of the semiconductor device shown in FIG. 1 taken along the line II-II. FIG. 3 is a cross-sectional view of the semiconductor device shown in FIG. 1 taken along the line III-III.

The semiconductor device has a semiconductor substrate 10. The semiconductor substrate 10 is defined as a semiconductor chip as shown in FIG. 1 from a viewpoint of the semiconductor device as a finished product, and is defined as a semiconductor wafer from the viewpoint of the semiconductor device as a partly finished product in the process of fabrication. The semiconductor substrate 10 is provided with at least one integrated circuit 12, in which the semiconductor chip in FIG. 1 is provided with the single integrated circuit 12 while the semiconductor wafer is provided with the plurality of integrated circuits 12. The integrated circuit 12 is formed on one surface layer of the semiconductor substrate 10. The semiconductor substrate 10 has a plurality of electrodes 14 which are electrically coupled to the single integrated circuit 12 through internal wirings formed inside the semiconductor substrate 10. The semiconductor substrate 10 is provided with a passivation film 16 in a manner to expose at least one part of the electrodes 14. The passivation film 16 may be made from an inorganic material, for example, inorganic oxide such as SiO₂.

The semiconductor substrate 10 is provided with a first resin layer 18 as a stress relaxation layer on a surface of the passivation film 16 provided with the electrodes 14, in a manner to have at least one part of the electrodes 14 uncovered with the first resin layer 18. For example, the first resin layer 18 may be formed by employing a photolithography with use of photosensitive resins. The first resin layer 18 may be formed with use of thermosetting resins. In the first resin layer 18, a side surface 19 may be inclined in a manner to set the acute angle between a bottom surface and the side surface 19. The side surface 19 is inclined by heat contraction of a thermosetting resin precursor. A cutter or scriber can be prevented from clogging by forming the first resin layer 18 in a manner to avoid cut lines of the semiconductor substrate 10 to be described later. A top surface of the first resin layer 18 is subjected to a surface roughening by means of a dry etching or the like.

Wirings 20 are formed on the top surface of the first resin layer 18. The wirings 20 are electrically coupled to the electrodes 14. Specifically, the wirings 20 are formed in a manner to extend from tops of the electrodes 14 up to the top surface of the first resin layer 18. The roughened top surface of the first resin layer 18, which has been subjected to the surface roughening, enhances intimate contact with the wirings 20 and shapes a contact surface between the wirings 20 and the first resin layer 18 in a manner to correspond to the roughened surface, thereby enabling the contact surface to have a larger area compared with that of a flat surface. The wirings 20 may be formed in contact with the passivation film 16 between the electrodes 14 and the first resin layer 18.

A metallic layer 22 is formed on the top surface of the first resin layer 18. In the metallic layer 22, a surface in parallel to the first resin layer 18 is formed in a polygonal shape such as a square. The metallic layer 22 is not formed on the side surface 19 of the first resin layer 18. The metallic layer 22 may be made from the same material as that of the wirings 20 and may be formed together with the wirings 20. The metallic layer 22 is electrically coupled to neither the wirings 20 nor the integrated circuit 12.

A second resin layer 24 such as a solder mask layer is formed on the first resin layer 18. The second resin layer 24 is mounted on the wirings 20 and the metallic layer 22. The second resin layer 24 is provided with first through holes 26 overlapped with the lands 21 as one part of the wirings 20 and second through holes 28 to expose one part of the metallic layer 22. The second through holes 28 are formed in the second resin layer 24 to expose end parts of the metallic layer 22 and parts of the first layer 18 exposing from the metallic layer 22, which are adjacent to the end parts of the metallic layer 22. The second through holes 28 are formed in the second resin layer 24 to expose corners of the metallic layer 22. In the semiconductor device as a finished product, the second through holes 28 are not filled up to thereby expose parts of the metallic layer 22.

The second resin layer 24 further has a plurality of third through holes 30 overlapped with the metallic layer 22. The third through holes 30 are placed so as not to expose the first resin layer 18. In other words, the metallic layer 22 is placed over an inner area surrounded by the third through holes 30.

Inside the first through holes 26, external terminals 32 are formed on the wirings 20, respectively. The external terminals 32 are set to a signal terminal or a power supply terminal to be electrically coupled to the integrated circuit 12. The external terminals 32 may be formed by means of soldering. For example, cream solder, which is first placed on the lands 21 of the wirings 20, may be melted and ball-shaped by surface tension. In the case of the semiconductor substrate 10 set to the semiconductor wafer, the semiconductor device can be obtained by cutting the semiconductor wafer by means of dicing or scribing.

Inside the plurality of third through holes 30, a plurality of metallic terminals 34 are formed on the metallic layer 22, respectively. The plurality of metallic terminals 34 are formed by forming least one metallic terminal 34 in each of the plurality of third through holes 30. The metallic terminals 34 may be considered as a dummy terminal because they, as a signal terminal or a power terminal, are not electrically coupled to the integrated circuit 12. The metallic terminals 34 may be made from the same material even in the same shape as those of the external terminals 32. The plurality of metallic terminals 34 and/or the plurality of the external terminals 32 are positioned at a plurality of intersection points of a plurality of first parallel straight lines L₁ with a plurality of second parallel straight lines L₂, which are perpendicular to the first straight lines L₁. The plurality of metallic terminals 34 and/or the plurality of the external terminals 32 are arranged in a manner to set uniform intervals between those adjacent terminals in arrays along either of the first and second straight lines L₁, L₂.

According to this embodiment, not only the external terminals 32 transfer heat through the wirings 20 but also the metallic layer 22 receives heat and the metallic terminals 34 transfer heat, thereby achieving heat release. Furthermore, the metallic layer 22 directly releases heat through the second through holes 28, and thus reduces the adverse effect on the motherboard by heat when the semiconductor device is mounted on the motherboard.

### Second Embodiment

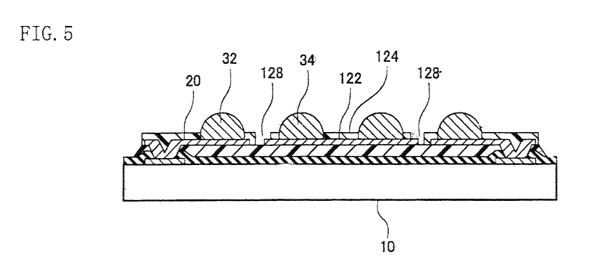

FIG. 4 is a view showing a semiconductor device according to the second embodiment of the invention. FIG. 5 is a cross-sectional view of the semiconductor device shown in FIG. 4 taken along the line V-V. In this embodiment, a second through hole 128 is formed in a second resin layer 124 in a manner to expose the whole of a periphery of a metallic layer 122. In other words, the second through hole 128 is formed in a ring shape. Details of the first embodiment described above are applied in point of the other structures and production methods. This embodiment also enables the metallic layer 122 to release heat through the second through hole 128.

### Third Embodiment

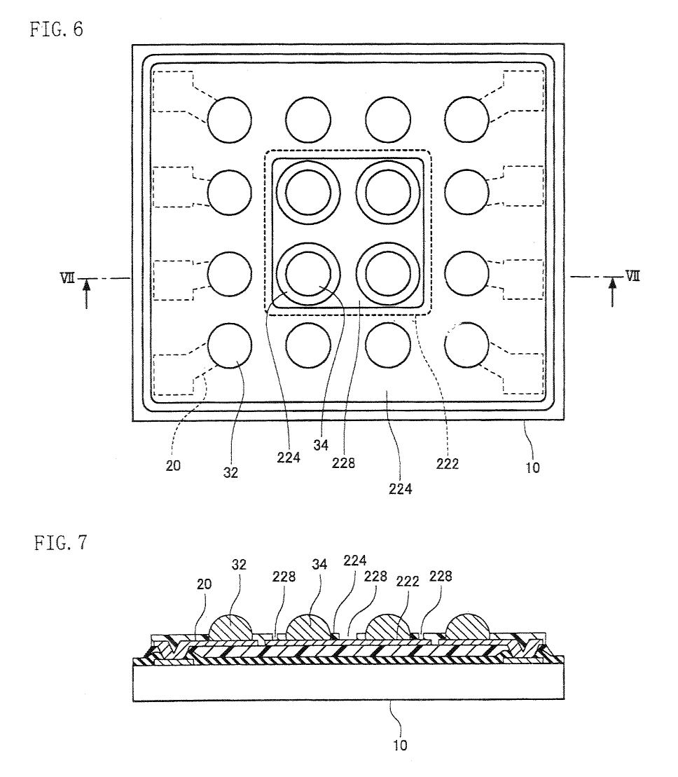

FIG. 6 is a view showing a semiconductor device according to a third embodiment of the invention. FIG. 7 is a cross-sectional view of the semiconductor device shown in FIG. 6 taken along the line VII-VII. In this embodiment, a second through hole 228 is formed in a second resin layer 224 in a manner to expose only a region inside a periphery of a metallic layer 222. In other words, the whole of the periphery of the metallic layer 222 is covered with the second resin layer 224. Since the second resin layer 224 is employed as a solder mask, the second resin layer 224 is also disposed around the metallic terminals 34. Details of the first embodiment described above are applied in point of the other structures and production methods. This embodiment also enables the metallic layer 222 to release heat through the second through hole 228.

This invention is not limited to the embodiments described above but may be variously modified. For example, this invention includes substantially the same structure including the structure with the same functions, methods, and results or the structure with the same goals and results as that of the embodiments described above. This invention also includes other structures in which non-essential elements of the above embodiments are substituted. This invention also includes the structures that can achieve the same effects or the same goals as those achieved by the above embodiments. Moreover, this invention includes other structures in which known methods and techniques are incorporated into the above embodiments.

What is claimed is:

1. A semiconductor device comprising:
a semiconductor substrate that is provided with an integrated circuit and an electrode electrically coupled to the integrated circuit;
a first resin layer that is formed on a surface of the semiconductor substrate, the surface of the semiconductor substrate being provided with the electrode;
a wiring that is electrically coupled to the electrode and formed on the first resin layer;
a metallic layer that is formed on the first resin layer;
a second resin layer that is provided with a first through hole overlapped with the wiring and a second through hole for exposing a part of the metallic layer; and
an external terminal that is formed inside the first through hole on the wiring.

2. The semiconductor device according to claim 1, wherein the second through hole is formed in a manner to expose an end part of the metallic layer and a part of the first resin layer adjacent to the end part of the metallic layer from the second resin layer.

3. The semiconductor device according to claim 1, wherein the second through hole is formed in a manner to expose an entire periphery of the metallic layer from the second resin layer.

4. The semiconductor device according to claim 1, wherein the metallic layer has a surface in parallel to the first resin layer, the surface formed in a polygonal shape, and wherein the second through hole is formed in a manner to expose a corner of the metallic layer from the second resin layer.

5. The semiconductor device according to claim 1, wherein the second resin layer covers the entire periphery of the metallic layer.

6. The semiconductor device according to claim 1, wherein the second resin layer is further provided with a third through hole overlapped with the metallic layer, and a metallic terminal formed inside the third through hole on the metallic layer.

7. The semiconductor device according to claim 6, wherein the third through hole includes a plurality of third through holes, and the metallic terminal is formed in a plurality of numbers by forming at least one metallic terminal inside each of the plurality of third through holes, the plurality of metallic terminals are positioned at a plurality of intersection points of a plurality of first parallel straight lines with a plurality of second parallel straight lines perpendicular to the first straight lines, and wherein the plurality of metallic terminals are arranged in a manner to set uniform intervals between the adjacent metallic terminals in arrays along either of the first and the second straight lines.
